(19) United States
(12) Patent Application Publication
(10) Pub. No.: US 2013/0026659 A1
(43) Pub. Date: Jan. 31, 2013

(54) MICROELECTRONIC COMPONENT

(71) Applicants: Mehmet Kaynak, Frankfurt (DE); Bernd Tillack, Frankfurt (DE); Rene Scholz, Halle (DE)

(72) Inventors: Mehmet Kaynak, Frankfurt (DE); Bernd Tillack, Frankfurt (DE); Rene Scholz, Halle (DE)

(73) Assignee: IHP GmbH - Innovations for High Performance Microelectronics, Frankfurt (DE)

(21) Appl. No.: 13/639,370

(22) PCT Filed: Mar. 22, 2011
(86) PCT No.: PCT/EP2011/054362

§ 371 Date: Oct. 4, 2012

(30) Foreign Application Priority Data
Apr. 13, 2010 (DE) 10 2010 003 928.4

(51) Int. Cl. H01L 23/522; H01L 21/768

(52) U.S. Cl. 257/786; 438/622; 257/E21.59; 257/E23.142

(57) ABSTRACT

A method for producing a MEMS component including the steps of simultaneously embedding structure elements during producing the multi-level conductive path layer stack which structure elements are to be subsequently exposed, subsequently producing a recess that extends from a substrate backside to the multi-level conductive path layer stack, exposing the micromechanical structure elements in the multi-level conductive path layer stack through the recess. In order to increase process precision a reference mask for defining a lateral position or a lateral extension of the micromechanical structure elements to be exposed is produced, wherein the reference mask is either arranged on the substrate front side between the substrate and the multi-level conductive path layer stack or in a layer of the multi-level conductive path layer stack which layer is more proximal to the substrate than the structure element to be exposed.

The invention relates to a microelectronic component, an intermediary product and a method for producing the microelectronic component, like e.g. an integrated MEMS component including a substrate which includes a preferably monolithically integrated microelectronic circuit and a multi level conductive path layer stack on a front side of the substrate.

The invention is subsequently described with reference to an MEMS component without limiting its general applicability. MEMS is an abbreviation that is customary in the art for a micro electromechanical system. A MEMS layer structure includes, for example, micromechanical structure elements which are configured in the multi-level conductive path layer stack, wherein the micromechanical structure elements of the MEMS layer structure can be mechanically movable or non-movable.

It is known that producing micromechanical structures can be facilitated by structuring different metal layers that are separated by insulation layers which are used for electrically connecting the microelectronic components that are being used for electrically connecting the microelectronic components that are generated on a silicon substrate, like e.g. transistors, which simultaneously also creates the micromechanical structures. Thus, it is particularly advantageous that micromechanical actuators and sensors are directly connected with electronic circuits as MEMS which is advantageous in particular for high frequencies in Gigahertz range. A solution of this type is described for example in WO 2009/003958. An MEMS according to this configuration has multiple applications, for example as a switch for high frequency signals or sensors.

It has proven advantageous that etching the micromechanical structure elements embedded in the multi-level conductive path layer stack clear for providing their mechanical movability is performed from the backside of the substrate through a local opening in the silicon of the substrate that continues to the front side of the substrate (subsequently designated recess). Thus, covering and passivating the integrated electronic circuit of the MEMS component can be performed on the substrate front side through a conventional method, so that the sensitive micromechanical components of the MEMS structure are optimally protected on the front side and hermetically sealed. The hermetic sealing of the micromechanical structure on the backside of the substrate can then be performed in a cost-effective manner before separating the chips, for example through wafer bonding, through a planar cover plate made from SiO₂ or Si.

It is a problem when producing this type of MEMS component that the masks used for exposing the micromechanical structure through etching from the backside has to be aligned with the masks which are used for producing the integrated electronic circuit and the initially still embedded micromechanical structure elements on the top side. In order to solve this problem, it is conceivable to use a camera which simultaneously captures a picture from the top side and from the bottom side of the substrate. It is also possible to use an infrared camera. However, these devices are either complex or have an excessive positioning error (offset) in view of the fact that is a small positioning error of the employed masks already suffices at a substrate thickness of 300 to 750 μm and dimensions of the micromechanical structure elements in the μm range in order to cause malfunctions. Additionally, deep etching for producing the recess in the substrate does not generate walls that are perpendicular to the surface of the substrate. Typically, a conical shape of the recess is generated which means that additional manufacturing tolerances have to be considered.

Thus, it is an object of the invention to propose a solution in which an offset of the mask sets that are being used for processing the front side and the backside for producing the MEMS is permitted with tolerances that are manageable during fabrication while higher manufacturing tolerances are permissible for deep Si-etching for producing the recess in the substrate.

This technical problem is solved in different aspects of the invention through a method according to claim 1, a microelectronic component according to claim 9 and an intermediary product according to claim 10. Embodiments of these different aspects of the invention are defined in the dependent claims.

According to a first aspect of the invention, a method is proposed for producing a microelectronic component including the steps:
embedding structure elements that are to be exposed in a multi-layer conductive path layer stack during producing the multi-layer conductive path layer stack on a substrate front side of a substrate;
producing a recess that extends from a substrate backside oriented away from the multi-level conductive path layer stack to the substrate front side oriented towards the multi-level conductive path layer stack;
exposing the structure elements in the multi-level conductive path layer stack by removing layer sections of the multi-level conductive path layer stack from the substrate backside through the recess.

In the method according to the invention, producing a reference mask for defining a lateral position or a lateral extension of the structure element to be exposed is either performed during producing the multi-layer conductive path layer stack or before producing the multi-layer conductive path layer stack, wherein the reference mask is either arranged on the substrate front side between the substrate and the multi-layer conductive path layer stack or in a layer of the multi-layer conductive path layer stack which layer is more proximal to the substrate compared to the structure element to be exposed and exposing the structure element is performed from the substrate backside through the recess in portions of a lateral extension of the recess not covered by the reference mask.

Through the method according to the invention, a larger error with respect to the structure elements that are embedded in the multi-level conductive path layer stack and to be exposed can be permitted when producing the recess. The position of the reference mask relative to the structure elements to be exposed has low tolerances due to the joint fabrication of the reference mask and the structure elements to be exposed during producing the multi-level conductive path layer stack on the substrate front side.

Subsequently, embodiments of the method according to the invention are being described.

The additional features of the respective embodiment can be combined with one another in order to form additional embodiments of the method. When producing the recess, through the method according to the invention, a higher error tolerance applies as recited supra. The method preferably initially includes producing a mask on the substrate backside for defining a lateral position and a lateral extension of the recess. Preferably the recess, is produced in the substrate through an etching process, in particular a deep etching process according to the Bosch method. Other methods that are known to a person skilled in the art, however, are also usable.

The subsequent removal of the layer sections of the multi-level conductive path layer stack advantageously includes wet chemical etching.

For this purpose, a first etch stopping layer is additionally produced on the substrate front side in an embodiment of the method, wherein producing the recess in the is substrate is terminated when reaching the etch stop layer and wherein the etch stop layer is partially or completely removed before removing the layer sections of the multi-level conductive path layer stack. Through using the first etch stop layer which protects the multi-level conductive path layer stack against impairment through the process for producing the recess, the concept according to the invention is expanded by an additional functional layer.

A mask configured as an aperture is used for example as a reference mask with at least one opening for defining the lateral position or the lateral extension of the micromechanical structure elements to be exposed in preferred embodiments. The mask is simultaneously generated and embedded in one embodiment besides ladder beams and micromechanical structure elements when producing the multi-level conductive path layer stack or when producing a polySi-level and the mask is exposed after producing the recess from the backside of the substrate.

The subsequent exposing of the structure elements is then performed through the aperture in the embedded reference mask whose position relative to the mechanical components is subject to low tolerances through its joint production on the front side.

The exposing is performed for example through a selective insulator etching process. In an advantageous process variant, the reference mask is used as a second etch stop layer. This way, also wet chemical etching can be laterally controlled in a very precise manner and etching errors can be avoided which can occur due to an offset or an excessive extension of the recess in the substrate during wet chemical etching.

In one embodiment, the reference mask is formed in a layer of the multi-level conductive path layer stack which level is also used for the connection conductors between various circuit components. This method keeps the method complexity low.

In applications of the method according to the invention that are of particular interest, embedding a structure element that is to be exposed in the multi-level conductive path layer stack during production of the multi-level conductive path layer stack includes an MEMS layer structure with micromechanical structure elements. Thus it is facilitated to produce MEMS components with a significantly improved yield, this means with a significantly reduced scrap rate.

A second aspect of the present invention relates to a microelectronic component, including:
a substrate that includes a substrate front side and a substrate backside oriented opposite from the substrate front side;
a multi-level conductive path layer stack on the substrate front side;
a recess in the substrate which extends from the substrate backside into the multi-level conductive path layer stack;
exposed structure elements in at least one level of the multi-level conductive path layer stack within a lateral extension of the recess; and
a reference mask on the substrate front side between the substrate and the multi-level conductive path layer stack, or a level of the conductive path layer stack that is more proximal to the substrate compared to the exposed structure element in order to define a lateral position or a lateral extension of the structure elements.

The microelectronic component according to the invention has the advantages that were described in conjunction with the method according to the first aspect of the invention. Performing the method according to the invention is represented in the structure of the microelectronic component according to the invention in that a reference mask is provided which is used in the production process for defining a lateral position or a lateral extension of the micromechanical structure elements in the preferred embodiment between the substrate and the multi level conductive path stack or in a layer of the multilevel conductive path stack that is arranged closer to the substrate compared to the exposed structure elements.

According to a third aspect of the present invention an intermediary product for producing a microelectronic component is provided including:
a substrate which includes a substrate front side and a substrate back side oriented opposite to the substrate front side;
a multilevel conductive path layer stack on the substrate front side; structure elements in at least one level of a multi level conductive path layer stack, which structure elements are to be exposed; and
a reference mask on the substrate front side between the substrate and the multi level conductive layer path or a layer of the multi level conductive path stack that is arranged more proximal to the substrate than the structure element to be exposed for defining a lateral position or a lateral extension of the structure element in the context of an etching process to be performed from the substrate back side for exposing the structure element.

The intermediary product according to a third aspect of the present invention differs from the microelectronic component according to the second aspect of the invention in that the substrate does not include recesses yet. The intermediary product according to the invention is typically produced in an end of line process and made commercially available for further processing for producing a microelectronic component according to the second aspect of the invention.

Subsequently embodiments of the microelectronic component and intermediary products are described together. The additional features of the subsequently described embodiments represent advantageous embodiment for the microelectronic component and also for the intermediary product.

As stated supra MEMS components are preferred embodiments of the microelectronic component.

Preferably the reference mask is embedded in a direct layer of the multi layer conductive path layer stack. Alternatively the reference mask can also be embedded in a layer of the multilayer conductive path layer stack, wherein the layer includes a metal conductive path. In other embodiments the reference mask is made from mono crystalline or poly crystalline silicone.

A semi conductor substrate, an insulator substrate or a metal substrate are particularly suitable for the substrate. For using existing industrial process technologies employing a silicone substrate that is provided in one embodiment is of great importance.

In an advantageous embodiment already recited supra the structure element that is exposed or to be exposed is a portion of a micromechanical component (MEMS).

Other embodiments according to the invention are subsequently described with reference to drawing figures, wherein:

FIG. 1 illustrates a prior art MEMS component;

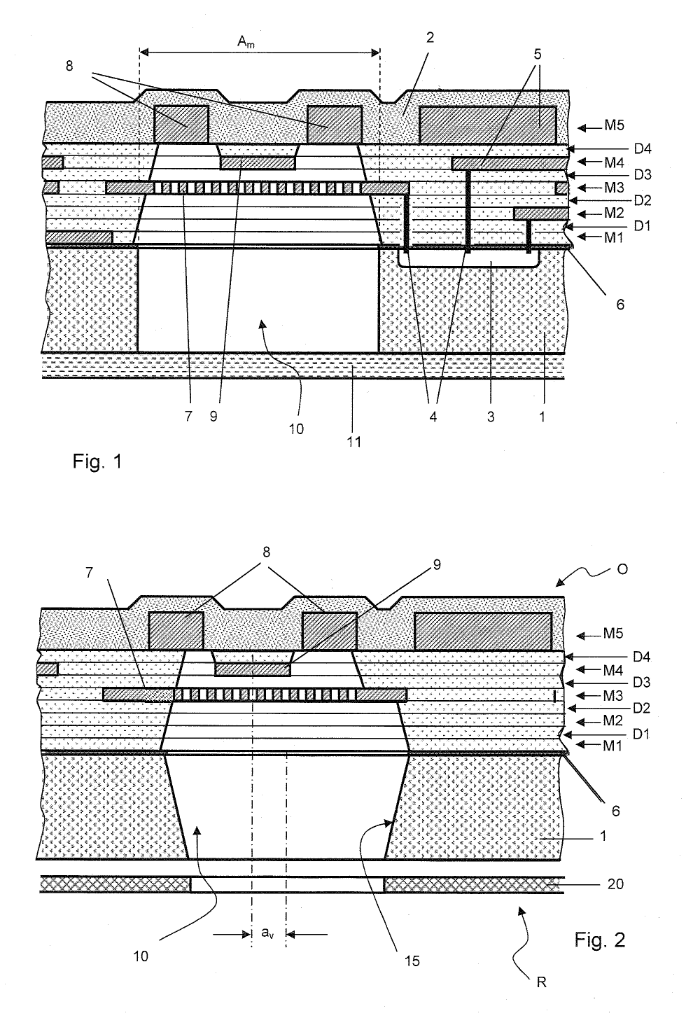

FIG. 2 illustrates a prior art MEMS component for describing voids in the configuration of structure elements which are generated in the prior art through a mask offset;

FIG. 3 illustrates a microelectronic component according to a first embodiment of the invention; and

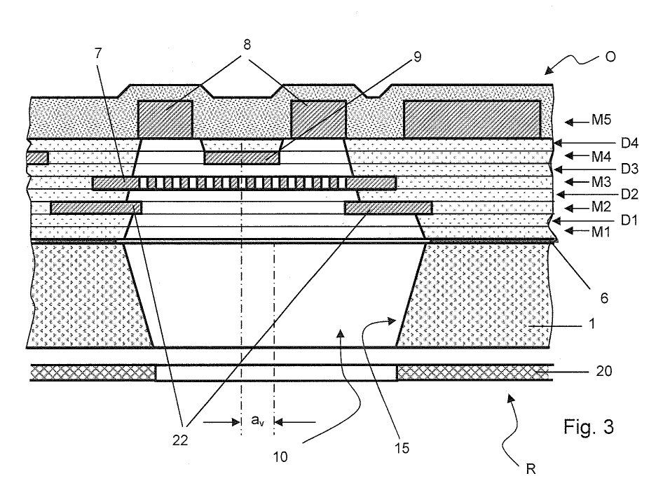

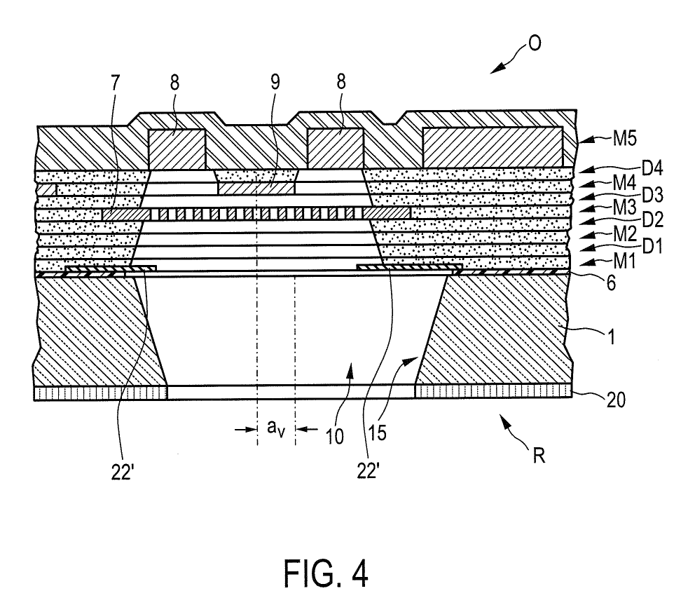

FIG. 4 illustrates a microelectronic component according to a second embodiment of the invention.

FIG. 1 illustrates a RF switch configured as a MEMS in a schematic transversal view as an example for a known prior art MEMS component that is suitable for being improved through the invention. The applicability of the invention, however, is not limited to an RF switch of this type but extends in particular to a plurality of MEMS like for example pressure sensors, acceleration sensors, pivot mirrors or non moving sensor elements. It is also configured for other components in which for example micro fluidic channels are to be exposed for cooling the microelectronic circuit, wherein the channels are arranged on a substrate front side.

Plural metallization planes M1-M5 are arranged on a silicone substrate 1, wherein the metallization planes are insulated from one another through dielectric materials D1-D4 which are structured accordingly and include conductive paths 5, 8 for electrically connecting the components 3 that are fabricated in the surface of the silicone substrate, but also include exposed micromechanical functional elements, for example a membrane 7. The conductive paths of various metallization planes are electrically connected with one another through Vias 4. Conductive paths 8 that are exposed from the substrate backside form an electrostatic drive together with the membrane 7, wherein the drive when a voltage is applied causes the membrane 7 to move to an electrode pedestal 9 that is also exposed and triggers a switching process. The component is provided on the substrate backside with a cover plate 11 for a recess 10 in the substrate 1.

FIG. 2 emphases the problem that is unsolved in the prior art with reference to a cross sectional view of a similar component, wherein the problem is created in when a mask 20 that is used for introducing the recess 10 into the silicone substrate 1 is not aligned precisely with reference to the structure elements 7, 8, 9 embedded in the multi level conductive path stack or with reference to the masks which were used for producing the structure elements. An offset aᵥ thus created has the effect that exposing the micro mechanical structure element is provided with errors which can eventually lead to the MEMS not being functional. In the present case the membrane 7 is not completely exposed.

FIG. 3 illustrates an embodiment of a microelectronic component according to the invention that is configured as a MEMS component, wherein the problem that is visible in FIG. 2 is solved with a reference mask 22. The structure of the MEMS component is otherwise identical with the structure already illustrated in FIGS. 1 and 2 in order to simplify the illustration.

Producing the component of FIG. 3 with structure elements to be exposed in the form of a MEMS structure formed by the micromechanical functional elements 7-9 is performed so that fabricating the electronic circuit elements like transistors etc. is performed directly on the surface of a front side O of the silicon wafer 1 that is acting as a substrate during the process steps of the so called front end of line. In the subsequent back end of line the electronic circuit elements are electrically connected with one another when producing a multi level conductive path layer stack on the substrate front side O through structuring metallization levels M1-M5 and the micromechanical functional elements 7-9 are additionally introduced.

During the production of a multi level conductive path layer stack also the reference mask 22 is introduced. The reference mask 22 forms a portion of the structured metallization plane M2 in the present embodiment but it can also be a portion of another plane in the back end. Alternatively it is possible to introduce the reference mask already in the front end of line, for example in a PolySi plane.

After completing the process steps, which relate to the top side of the MEMS a recess 10 is introduced into the substrate 1 through the mask 20 for exposing the micromechanical structure elements 7, 8, 9 through a silicone deep etching process. A silicon nitride layer 6 is used as an etching stop for the deep etching process. The dimensions of the recess 10 are thus selected greater than the dimensions of the micromechanical structure elements 7, 8, 9 in order to assure that these structure elements are above the recess also for a tolerance induced offset. Typically the recess expands in lateral direction during the deep etching process which is illustrated by the side walls 15 of the recess 10 extending at a slant angle.

Exposing the micro mechanical functional elements 7-9 is performed from the substrate back side R after producing the recess 10. Initially the etching stop layer 6 is opened in the portion of the recess 10. The actual exposing of the micro mechanical functional elements through wet etching methods initially leads to the reference mask 22 and continues through the illustrated opening in the reference mask 22 through the following conductive path levels M3-M5 and insulator levels D2-D4. In order to expose the space between the electrode pedestal 9 and the membrane 7 the membrane 7 is perforated.

In this wet etching process the reference mask 22 defines the lateral position and the lateral extension of the exposed layer sections above the reference mask 22 and thus prevents errors as illustrated in FIG. 2. Since the opening in the reference mask 22 was produced together with the micro mechanical functional elements from the top side of the substrate, exposing the micro mechanical functional elements is referenced to the reference mask 22 and not to the mask 20 which is used on the substrate backside R. Thus, the MEMS structure 7, 8, 9 is exposed with the significantly improved tolerances of the reference plane 22. The relieving is substantially insensitive with respect to a possibly erroneous positioning of the mask 20.

FIG. 4 illustrates a variant of the embodiment of FIG. 3. The micro electronic component of FIG. 4 differs from the micro electronic component of FIG. 3 only in that another reference mask 22′ is being used. The reference mask 22′ is arranged between the substrate and the multi level conductive layer stack in a PolySi level. Thus, the reference mask 22′ differently from the embodiment of FIG. 3 is already introduced in the front end of line in the context of the production process of the micro electronic component. Thus, the reference mask 22′ is also fabricated from poly-silicone.

As a matter of principle the variants of FIGS. 3 and 4 are equally useable. The variant of FIG. 4, however, is better suited when the multi level conductive path layer stack has a smaller number of layer levels or includes micro mechanical functional elements that extend over plural layer levels and are to be exposed, wherein the functional elements do not leave any space in the multi level conductive path layer stack for the reference mask to be arranged there under.

Only for better clarity FIG. 4 illustrates essentially the same component as FIG. 3. The variant of FIG. 4 with a reference mask between the substrate and the multi level conductive path layer stack is certainly also useable for other micro electronic components in which any structure that is embedded in the multi level conductive path layer stack is to be exposed

What is claimed is:

1. A method for producing a microelectronic component, comprising:
embedding structure elements (7, 8, 9) that are to be exposed in a multi-level conductive path layer stack on a substrate front side of a substrate (1) during producing the multi-level conductive path layer stack;
producing a recess that extends from a substrate backside (R) oriented away from the multi-level conductive path layer stack to the substrate front side (V) oriented towards the multi-level conductive path layer stack;
exposing the structure elements in the multi-level conductive path layer stack by removing layer sections of the multi-level conductive path layer stack from the substrate backside through the recess;
producing a reference mask (22) for defining a lateral position or a lateral extension of the structure element (7, 8, 9) to be exposed either during producing the multi-level conductive path layer stack or before producing the multi-level conductive path layer stack,
wherein the reference mask (22) is either arranged on the substrate front side between the substrate (1) and the multi-level conductive path layer stack or in a layer of the multi-level conductive path layer stack which layer is more proximal to the substrate (1) compared to the structure element to be exposed; and
exposing the structure element is performed from the substrate backside through the recess in portions of a lateral extension of the recess not covered by the reference mask.

2. The method according to claim 1, wherein producing the recess includes producing a mask (20) on the substrate back side for defining a lateral position and a lateral extension of the recess.

3. The method according to claim 1, wherein producing the recess (10) in the substrate (1) includes performing a deep etching process according to the Bosch method.

4. The method according to claim 1, wherein removing the layer sections (D2, D3) of the multi level conductive path layer stack (MLS) includes wet chemical etching.

5. The method according to claim 4, wherein a first etch stop layer is additionally produced on the substrate front side, wherein producing the recess in the substrate is terminated when the etch stop layer is reached and wherein the etch stop layer is partially or completely removed before removing layer sections of the multi level conductive path layer stack.

6. The method according to claim 4, wherein the reference mask forms a second etch stop layer and includes at least one opening for defining the lateral position or the lateral extension of the structure element (7, 8, 9) to be exposed.

7. The method according to claim 1, wherein the reference mask is formed in a layer level of the multi level conductive path layer stack, wherein the layer level is also used for connecting conductors between various circuit elements.

8. The method according to claim 1, wherein embedding a structure element (7, 8, 9) in the multi level conductive path layer stack, wherein the structure element is to be exposed, includes producing a MEMS layer structure (MEM) with micro mechanical structure elements (7, 9) during producing the multi level conductive path layer stack (MLS).

9. A microelectronic component, comprising:
a substrate that includes a substrate front side and a substrate backside oriented opposite from the substrate front side;
a multi-level conductive path layer stack on the substrate front side;
a recess in the substrate which extends from the substrate backside into the multi-level conductive path layer stack; and
exposed structure elements (7, 8, 9) in at least one level of the multi-level conductive path layer stack within a lateral extension of the recess,
wherein the microelectronic component includes a reference mask (22, 22′) on the substrate front side between the substrate and the multi-level conductive path layer stack or in a layer of the conductive path layer stack that is more proximal to the substrate compared to the exposed structure element in order to define a lateral position or a lateral extension of the structure elements.

10. An intermediary product for producing a microelectronic component, the intermediary product comprising:
a substrate which includes a substrate front side and a substrate back side oriented opposite to the substrate front side;
a multilevel conductive path layer stack on the substrate front side;
structure elements that are to be exposed in at least one level of a multi level conductive path layer stack; and
a reference mask (22, 22′) for defining a lateral position or a lateral extension of the structure elements (7, 8, 9) for an etching process to be performed from the substrate back side for exposing the structure element, wherein the reference mask is either arranged on the substrate front side between the substrate (1) and the multi-level conductive path layer stack or in a layer of the multi-level conductive path layer stack which layer is more proximal to the substrate (1) compared to the structure element to be exposed.

11. The micro electronic component or intermediary product according to claim 9, wherein the exposed structure element or the structure element to be exposed forms a micro mechanical component or a portion thereof.

12. The intermediary product according to claim 10, wherein the reference mask is embedded in a dielectric layer of the multilevel conductive path layer stack.

13. The intermediary product according to claim 10, wherein the reference mask is embedded in a layer of the multi level conductive path layer stack which includes metal conductive paths.

14. The intermediary product according to claim 10, wherein the reference mask is made from mono crystalline or poly crystalline silicone.

15. The intermediary product according to claim 10, wherein the substrate is a semi conductor substrate, an insulator substrate or a metal substrate.

16. The micro electronic component according to claim 9, wherein the reference mask is embedded in a dielectric layer of the multilevel conductive path layer stack.

17. The micro electronic component according to claim 9, wherein the reference mask is embedded in a layer of the multi level conductive path layer stack which includes metal conductive paths.

18. The micro electronic component according to claim 9, wherein the reference mask is made from mono crystalline or poly crystalline silicone.

19. The micro electronic component according to claim 9, wherein the substrate is a semi conductor substrate, an insulator substrate or a metal substrate.
